(19) United States
(12) Patent Application Publication
(10) Pub. No.: US 2024/0196613 A1
(43) Pub. Date: Jun. 13, 2024

(54) SEMICONDUCTOR INTEGRATED CIRCUIT DEVICE INCLUDING SPLIT SELECTION LINES AND METHOD OF MANUFACTURING THE SEMICONDUCTOR INTEGRATED CIRCUIT DEVICE

(71) Applicant: SK hynix Inc., Icheon-si Gyeonggi-do (KR)

(72) Inventor: Jin Su PAK, Icheon-si Gyeonggi-do (KR)

(73) Assignee: SK hynix Inc., Icheon-si Gyeonggi-do (KR)

(21) Appl. No.: 18/356,951

(22) Filed: Jul. 21, 2023

(30) Foreign Application Priority Data
Dec. 7, 2022 (KR) 10-2022-0169938

(51) Int. Cl. H10B 43/27; G11C 5/06; G11C 16/04; H10B 41/10; H10B 41/27; H10B 43/10

(52) U.S. Cl. CPC H10B 43/27; G11C 5/063; G11C 16/0483; H10B 41/10; H10B 41/27; H10B 43/10

(57) ABSTRACT

A semiconductor integrated circuit device includes a stack structure, a split structure, a plurality of channel structures and at least one boundary channel structure. The stack structure includes a plurality of insulation layers and a plurality of conductive layers alternately stacked in a first direction. The split structure is configured to split at least one selected conductive layer among the conductive layers from the insulation layers adjacent to the selected conductive layer. The channel structures are spaced apart from the split structure. The channel structures are arranged in the stack structure. The boundary channel structure is partially overlapped with the split structure. The boundary channel structure is arranged in the stack structure.

### CROSS-REFERENCES TO RELATED APPLICATION

The present application claims priority under 35 U.S.C. § 119(a) to Korean application number 10-2022-0169938, filed on Dec. 7, 2022, in the Korean Intellectual Property Office, which is incorporated herein by reference in its entirety.

### BACKGROUND

### 1. Technical Field

Various embodiments generally relate to a semiconductor integrated circuit device and a method of manufacturing the same, more particularly, to a semiconductor integrated circuit device including split selection lines and a method of manufacturing the semiconductor integrated circuit device.

### 2. Related Art

A three-dimensional (3D) semiconductor memory device may be developed for improving the integration degree of a semiconductor memory device. The three-dimensional semiconductor memory device may include a plurality of memory cells arranged in a three-dimension to reduce an area of the memory cells in a unit area, thereby improving the integration degree.

A typical 3D NAND memory device of the 3D semiconductor memory device may require an arrangement of a plurality memory cell strings in a limited area, for example, a memory block. Further, in order to selectively drive the memory cell strings in the memory block, it may be required to split selection lines in the memory block.

Recently, in order to split the selection lines, a split structure may be formed in a stack structure.

### SUMMARY

According to various embodiments, there may be provided a semiconductor integrated circuit device. The semiconductor integrated circuit device may include a stack structure, a split structure, a plurality of channel structures and at least one boundary channel structure. The stack structure may include a plurality of insulation layers and a plurality of conductive layers alternately stacked in a first direction. The split structure may be configured to split at least one selected conductive layer among the conductive layers from the insulation layers adjacent to the selected conductive layer. The channel structures may be spaced apart from the split structure. The channel structures may be arranged in the stack structure. The boundary channel structure may be partially overlapped with the split structure. The boundary channel structure may be arranged in the stack structure. A first cut surface of the selected conductive layer split by the split structure is positioned a first distance from a center of the split structure. A second cut surface of each of the insulation layers split by the split structure are respectively positioned a second distance from the center of the split structure.

According to various embodiments, there may be provided a semiconductor integrated circuit device. The semiconductor integrated circuit device may include a stack structure, a plurality of channel structures and a split structure. The stack structure may include at least one source selection line, a plurality of word lines and at least one drain selection line stacked in a first direction. An insulation layer may be interposed between the source selection line, the word lines and the drain selection line. Each of the channel structures may include a cylindrical channel layer extended in the stack structure along the first direction to face the source selection line, the word lines and the drain selection line. The split structure may be configured to split at least one of the drain selection line, which may be extended in a second direction substantially perpendicular to the first direction, and the channel structures. A cut surface of the drain selection line may be positioned outside a cut surface of the channel structure split by the split structure with respect to a center line of the split structure. An impurity concentration of the channel layer in the channel structures partially split by the split structure may be higher than an impurity concentration of the channel layer in the channel structures spaced apart from the split structure. A cut surface of the insulation layer split by the split structure may be positioned inside the cut surface of the drain selection line with respect to the center line of the split structure.

According to various embodiments, there may be provided a method of manufacturing a semiconductor integrated circuit device. In the method of manufacturing the semiconductor integrated circuit device, a plurality of insulation layers and a plurality of conductive layers may be alternately stacked to form a stack structure including at least one source selection line, a plurality of word lines and at least one drain selection line. A plurality of channel structures including cylindrical channel layers may be formed in the stack structure. A split hole may be formed in the stack structure to split at least one of the drain selection line of the stack structure and the channel structures. The drain selection line exposed through a sidewall of the split hole may be recessed. First conductive type impurities may be selectively implanted into the channel layer of the split channel structure exposed through the sidewall of the split hole. A buried insulation layer may be formed in the split hole to form a split structure.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a circuit diagram illustrating a memory block of a 3D semiconductor memory device in accordance with various embodiments.

FIG. 2 is a plan view illustrating a memory block in accordance with various embodiments;

FIG. 3 is a cross-sectional view taken along a line I-I′ in FIG. 2;

FIG. 4 is a plan view illustrating a channel structure in accordance with various embodiments;

FIG. 5 is a plan view illustrating a boundary channel structure with a split structure in accordance with various embodiments;

FIG. 6 is a cross-sectional view illustrating a split hole just after forming the split hole in accordance with various embodiments;

FIG. 7 is a cross-sectional view illustrating a split hole after a recess process in accordance with various embodiments;

FIG. 8 is a plan view illustrating a boundary channel structure with a split structure in accordance with various embodiments;

FIG. 9 is a perspective view illustrating a boundary channel structure in accordance with various embodiments; and

FIGS. 10A, 10B, 10C, and 10D are cross-sectional views illustrating a method of manufacturing a semiconductor integrated circuit device in accordance with various embodiments.

### DETAILED DESCRIPTION

Various embodiments of the present application will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present embodiments as defined in the appended claims. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

The present embodiments described herein are with reference to cross-section and/or plan illustrations. However, these embodiments should not be construed as limiting. Although a few embodiments will be shown and described, it will be appreciated by those of ordinary skill in the art that changes may be made in these embodiments without departing from the principles and spirit of the present disclosure.

According to an embodiment, when the split structure may be formed, the conductive layers for the drain selection line exposed through the sidewall of the split structure, which may be caused by non-uniformity of an etching between the conductive layer and the insulation layer, may be recessed. Thus, damage to the sidewall of the split structure may be reduced.

According to an embodiment, boron ions may be implanted into the channel layer of the boundary channel structure split by the split structure to compensate characteristics of a selection transistor connected to the boundary channel structure.

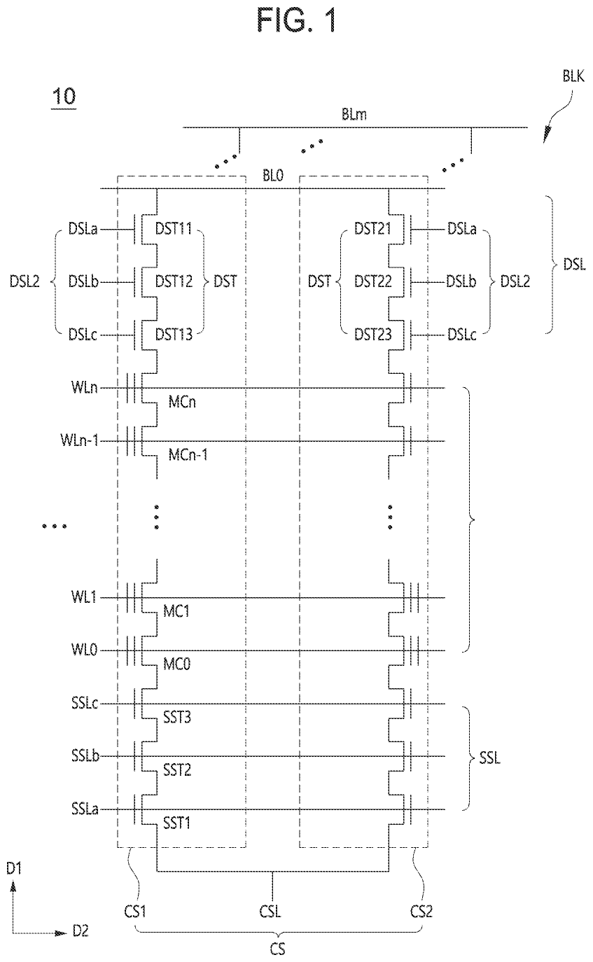

FIG. 1 is a circuit diagram illustrating a memory block of a 3D semiconductor memory device in accordance with various embodiments.

Referring to FIG. 1, a semiconductor integrated circuit device 10, for example, a 3D semiconductor memory device may include a memory cell array and a control circuit block configured to drive the memory cell array. The memory cell array and the control circuit block may be arranged in a horizontal direction or a vertical direction.

The memory cell array may include at least one memory block BLK. For example, the memory block BLK may include a plurality of memory cells MC1˜MCn. The memory cells MC1˜MCn in the memory block BLK may simultaneously perform a data erase process by a single operation. As used herein, the tilde “˜” indicates a range of components. For example, “MC1˜MCn” indicates the memory cells MC1, MC2, . . . , and MCn shown in FIG. 1. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The memory block BLK may include a plurality of word lines WL0˜WLn and a plurality of bit lines BL0˜BLm. The memory cells MC1˜MCn may be formed between the word lines WL0˜WLn and the bit lines BL0˜BLm.

In various embodiments, the memory block BLK may include a plurality of memory cell strings CS. Each of the memory cell strings CS may include at least one source selection transistor SST1˜SST3, a plurality of memory cells MC0˜MCn and at least one drain selection transistor DST1˜DST3 serially connected with each other. The source selection transistor SST1˜SST3, the memory cells MC0˜MCn and the drain selection transistor DST1˜DST3 may be serially connected between a common source line CSL and a bit line BL. For example, the source selection transistor SST1˜SST3, the memory cells MC0˜MCn and the drain selection transistor DST1˜DST3 in the memory cell strings CS may commonly share one channel layer.

A gate of the source selection transistor SST1˜SST3 may be connected to source selection lines SSL1˜SSL3 to be driven. The memory cells MC0˜MCn may be connected to the word lines WL0˜WLn to store data. A gate of the drain selection transistor DST1˜DST3 may be connected to drain selection lines DSL1˜DSL3. In FIG. 1, numbers of the source selection line and the drain selection line may be changed in accordance with different types of devices.

In various embodiments, a first memory cell string CS1 and a second memory cell string CS2 may be connected between a bit line BL0 and a common source line CSL. The memory cells MC0˜MCn of the first memory cell string CS1 and the memory cells MC0˜MCn of the second memory cell string CS2 may be controlled by the same word lines WL0˜WLn. Thus, the first memory cell string CS1 and the second memory cell string CS2 may be parallely connected with each other.

In order to prevent the first memory cell string CS1 and the second memory cell string CS2 connected to the same bit line BL from being simultaneously driven, the drain selection line DSL may be split into a first drain selection line group DSL1 and a second drain selection line group DSL2. Thus, the first memory cell string CS1 may be controlled by the first drain selection line group DSL1. The second memory cell string CS2 may be controlled by the second drain selection line group DSL2 split from the first drain selection line group DSL1.

In various embodiments, when each of the first memory cell string CS1 and the second memory cell string CS2 may include the first to third drain selection transistors DST11˜DST13, each of the split first and second drain selection line groups DSL1 and DSL2 may include first to third sub-drain selection lines DSLa˜DSLc.

The bit line BL may receive various voltages for performing a memory operation of the memory cell string CS connected to the bit line BL. The common source line CSL may receive a voltage for discharging data in the selected memory cell string CS. In various embodiments, the common source line CSL may include a conductive line formed at a semiconductor substrate or an additional conductive layer.

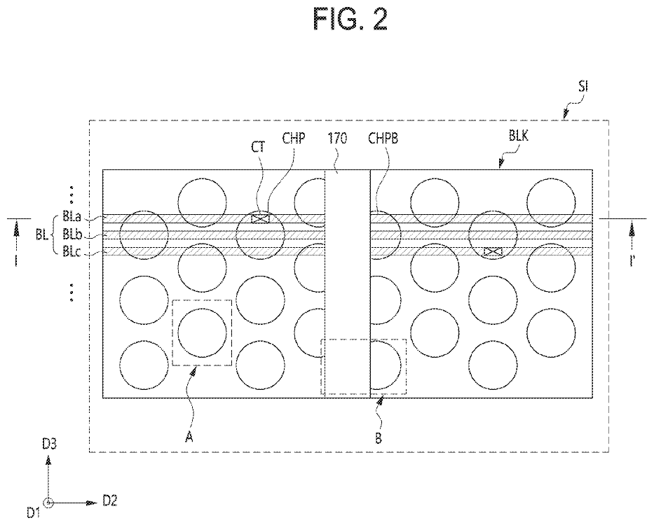

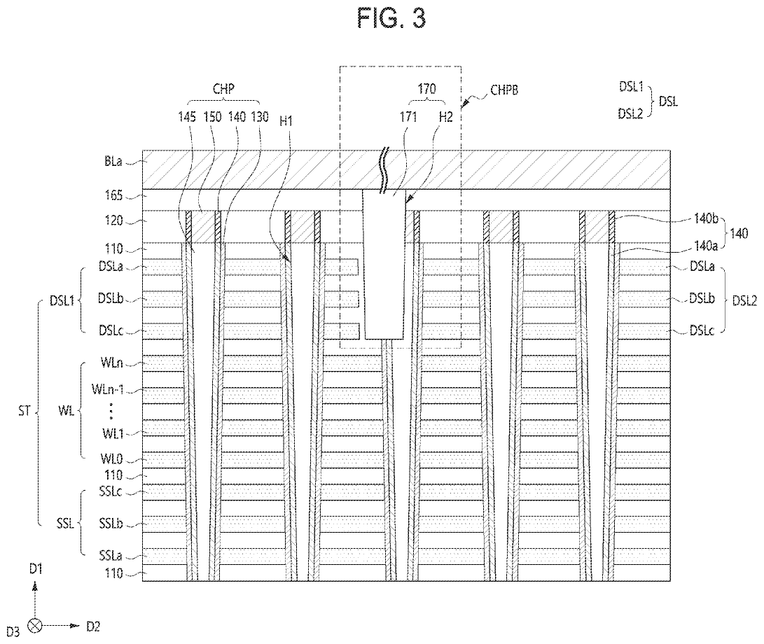

FIG. 2 is a plan view illustrating a memory block in accordance with various embodiments and FIG. 3 is a cross-sectional view taken along a line I-I′ in FIG. 2.

Referring to FIGS. 2 and 3, the memory block BLK may include a stack structure ST, a plurality of channel structures CHP and a plurality of bit lines BL.

The stack structure ST may include a source selection line SSL, a plurality of word lines WL0˜WLn and a drain selection line DSL sequentially stacked in a first direction D1. The source selection line SSL, the word lines WL0˜WLn and the drain selection line DSL may be overlapped with each other. An insulation layer may be interposed between the source selection line SSL, the word lines WL0˜WLn and the drain selection line DSL.

In various embodiments, the first direction D1 may be a vertical direction or a stack direction with respect to an upper surface of a substrate. A second direction D2 may be substantially perpendicular to the first direction D1. The second direction D2 may be any one of directions parallel to the upper surface of the substrate, for example, a row direction. A third direction D3 may be any one of the directions parallel to the upper surface of the substrate. The third direction D3 may be a column direction substantially perpendicular to the first and second directions D1 and D2. Hereinafter, a plane surface may be a surface extended in the second direction D2 and the third direction D3. A 3D structure of the memory device may be defined by planes extended in the first to third directions D1, D2 and D3.

In various embodiments, the source selection line SSL may include first to third sub-source selection lines SSLa, SSLb and SSLc. The drain selection line DSL may include first to third sub-drain selection lines DSLa, DLSb and DSLc. The first to third sub-source selection lines SSLa, SSLb and SSLc, the word lines WL0˜WLn and the first to third sub-drain selection lines DSLa, DSLb and DSLc may be sequentially stacked. A first insulation layer 110 may be interposed between the first to third sub-source selection lines SSLa, SSLb and SSLc, the word lines WL0˜WLn and the first to third sub-drain selection lines DSLa, DSLb and DSLc. The first to third sub-source selection lines SSLa, SSLb and SSLc, the word lines WL0˜WLn and the first to third sub-drain selection lines DSLa, DSLb and DSLc may be extended in the second and third directions D2 and D3.

In various embodiments, the word lines WL0˜WLn for selecting the memory cells MC0˜MCn may transmit a voltage higher than voltages of the first to third sub-source selection lines SSLa, SSLb and SSLc and the first to third sub-drain selection lines DSLa, DSLb and DSLc. Thus, thicknesses of the word lines WL0˜WLn may be thicker than thicknesses of the first to third sub-source selection lines SSLa, SSLb and SSLc and thicknesses of the first to third sub-drain selection lines DSLa, DSLb and DSLc.

Each of the first to third sub-source selection lines SSLa, SSLb and SSLc, the word lines WL0˜WLn and the first to third sub-drain selection lines DSLa, DSLb and DSLc may include at least one conductive layer. Alternatively, each of the first to third sub-source selection lines SSLa, SSLb and SSLc, the word lines WL0˜WLn and the first to third sub-drain selection lines DSLa, DSLb and DSLc may include a barrier layer and a conductive layer sequentially stacked. The conductive layer may include a metal layer such as a tungsten layer, not limited thereto.

The stack structure ST may be divided by a slit structure SI to define the memory block BLK. The slit structure SI may have an insulation plug shape, not limited thereto.

The stack structure ST may include at least one insulating interlayer configured to isolate the drain selection line DSL from the bit line.

In various embodiments, the stack structure ST may include a first insulating interlayer 120 and a second insulating interlayer 165. The first and second insulating interlayer 120 and 165 may have a thickness thicker than a thickness of the first insulation layer 110.

For example, the first insulating interlayer 120 may be configured to surround an upper region of the channel structures CHP. The second insulating interlayer 16 may include a contact plug CT configured to connect an upper surface of the channel structure CHP with the bit line BL.

A plurality of the bit lines BL may be extended in the second direction D2. The bit lines BL may be parallely arranged. A plurality of the bit lines BLa, BLb and BLc may be overlapped with one channel structure CHP. Any one of the overlapped bit lines BLa, BLb and BLc may be electrically connected with the contact plug CT.

The channel structures CHP may be formed in the stack structure ST. In various embodiments, the channel structures CHP may have a minimum width. So far as possible numbers of the channel structures CHP may be integrated in the stack structure ST. As shown in FIG. 2, in an embodiment, in order to integrate maximum numbers of the channel structures CHP, the channel structures CHP may be arranged in various patterns along the second direction D2 and the third direction D3. Each of the channel structures CHP may be vertically formed through the stack structure ST.

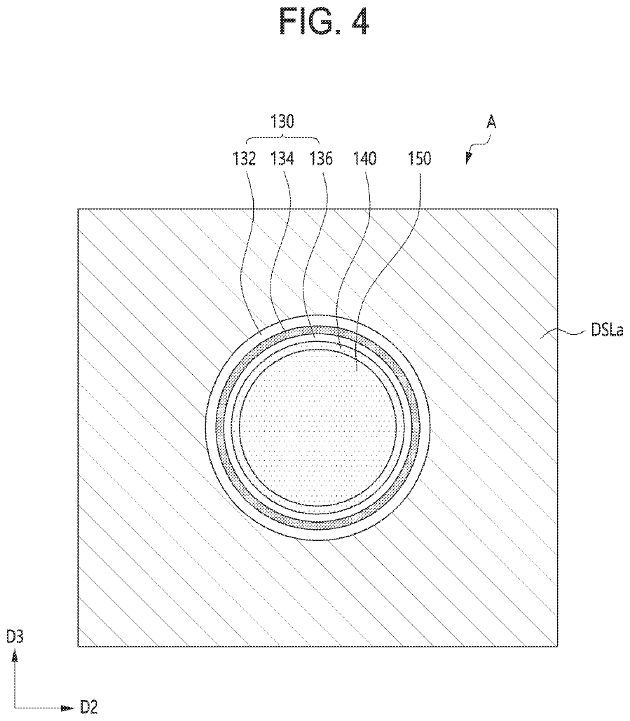

FIG. 4 is a plan view illustrating a channel structure in accordance with various embodiments. FIG. 4 may show a portion “A” in FIG. 2 except for a bit line.

Referring to FIG. 4, each of the channel structures CHP may have a cylindrical shape formed in the stack structure ST. The channel structure CHP may be arranged in a cylindrical channel hole H1 formed through the stack structure ST. Each of the channel structures CHP and the conductive layers of the stack structure ST on the channel structure CHP such as the source selection line, the word lines and the drain selection lines may form the memory cell string in FIG. 1.

As shown in FIGS. 3 and 4, each of the channel structures CHP may include a memory layer 130, a channel layer 140, a core insulation layer 145 and a capping pattern 150.

The memory layer 130 may be formed on a sidewall of the channel hole H1 in which the channel structure CHP may be formed later. The memory layer 130 may include a blocking insulating layer 132, a data storage layer 134 and a tunnel insulation layer 136. The blocking insulation layer 132 may be formed on an inner surface of the channel hole H1. The data storage layer 134 may be formed on an inner surface of the blocking insulation layer 132. The data storage layer 134 may include a material for storing charges by Fowler-Nordheim such as a charge-trapping material. Alternatively, the data storage layer 134 may include a material having resistance characteristics changed by an electric field of the corresponding conductive layer such as the source selection line, the word line and the drain selection line and the channel layer 140. In various embodiments, the data storage layer 134 may include a silicon nitride layer, a phase changeable layer, a nano-dot material, etc. The tunnel insulation layer 136 may be formed on an inner surface of the data storage layer 134. The tunnel insulation layer 136 may have a thickness for allowing a tunneling of the charge when a voltage may be applied to the corresponding conductive layer. For example, the blocking insulation layer 132 and the tunnel insulation layer 136 may include a silicon oxide layer.

The channel layer 140 may be formed on an inner surface of the memory layer 130. Thus, the channel layer 140 may also have a cylindrical shape similarly to the cylindrical shape of the channel hole H1. The channel layer 140 may include a semiconductor layer. In various embodiments, the channel layer 140 may include a semiconductor layer having conductive impurities. The channel layer 140 may include first conductive type impurities, for example, p type impurities having a first concentration. The first conductive type impurities may include boron. A concentration of the first conductive type impurities in the channel layer 140 may be determined considered a threshold voltage concentration of a transistor in the memory cell string.

The channel hole H1 may be filled with the core insulation layer 145 and the capping pattern 150. In various embodiments, the core insulation layer 145 may almost fully fill the channel hole H1. The capping pattern 150 may be formed in an upper space of the channel hole H1 above the core insulation layer 145. The core insulation layer 145 may be formed in a lower space of the channel hole H1 under the capping pattern 150. For example, the core insulation layer 145 may include an insulation layer having a low-K with good gap-filling characteristic.

In various embodiments, the capping pattern 150 may be positioned on the first insulating interlayer 120. For example, the capping pattern 150 may be formed in the upper space of the channel hole H1 defined between the first insulating interlayers 120. The capping pattern 150 may have a bottom surface higher than an upper surface of the first sub-drain selection line DSLa. The capping pattern 150 may include a semiconductor layer having second conductive type impurities opposite to the first conductive type impurities. For example, the capping pattern 150 may include n type impurities having a high concentration, for example, phosphorous ions. The capping pattern 150 may correspond to a drain contact configured to electrically connect the bit line with the memory cell string.

Further, the channel layer 140 may include a first channel region 140a and a second channel region 140b. The first channel region 140a may be configured to make contact with a sidewall of the core insulation layer 145. The second channel region 140b may be configured to make contact with a sidewall of the capping pattern 150. Because the first channel region 140a may be operated as an actual channel of the transistors in the memory cell string, the first channel region 140a may include first conductive type impurities. In contrast, the second channel region 140b may have a first conductive type when a deposition process. However, because the second channel region 140b may make contact with the capping pattern 150, the second channel region 140b may have a second conductive type due to an inflow of the second conductive type impurities having the high concentration from the capping pattern 150.

The memory block BLK may include at least one split structure 170 configured to split the drain selection line DSL into a plurality of drain selection line groups DSL1 and DSL2.

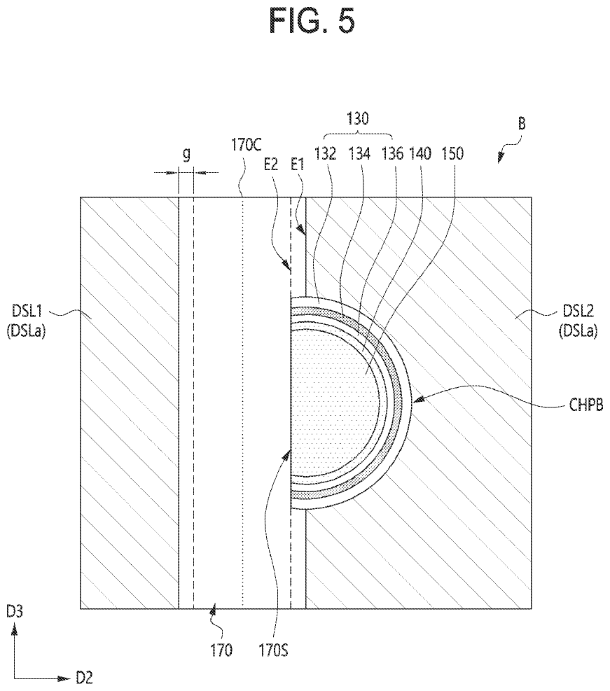

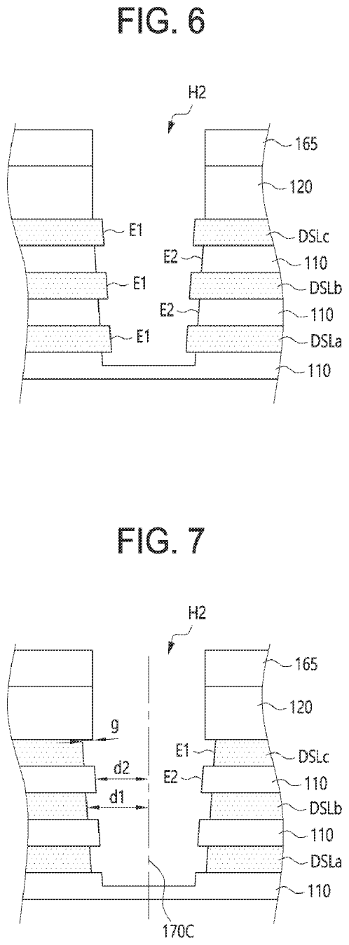

FIG. 5 is a plan view illustrating a boundary channel structure with a split structure in accordance with various embodiments, FIG. 6 is a cross-sectional view illustrating a split hole just after forming the split hole in accordance with various embodiments and FIG. 7 is a cross-sectional view illustrating a split hole after a recess process in accordance with various embodiments. In FIGS. 5 to 7, a structure of a bit line may be omitted for conveniences of explanations.

Referring to FIGS. 2 to 4, a planar structure of the split structure 170 may be extended in the third direction D3 substantially perpendicular to the second direction D2 to split the drain selection line DSL along the second direction D2. Further, as shown in FIG. 3, a cross-sectional structure of the split structure 170 may have a depth from an upper surface of the stack structure ST to split only the drain selection line DSL.

In various embodiments, the split structure 170 may split the drain selection line DSL into a first drain selection line group DSL1 and a second drain selection line group DSL2. In order to provide the first and second drain selection line groups DSL1 and DSL2 with a same function, the split structure 170 may be positioned at a central portion of the memory block BLK, i.e., a central portion of the stack structure ST defined by a shape of the memory block BLK.

For example, when the drain selection line DSL may include the first to third sub-drain selection lines DSLa, DSLb and DSLc, the first and second drain selection line groups DSL1 and DSL2 may also include the first to third sub-drain selection lines DSLa, DSLb and DSLc.

Here, a conventional split structure may be formed in a region where a channel structure might not be formed so that an integration degree of a memory device may be decreased.

Further, in an embodiment, a split structure may be configured to partially occupy channel structures to increase an integration degree. However, because a part of an area may be lost by the split structure in a channel structure with the split structure, the channel structure with the split structure may have a function different from a function of a normal channel structure having a normal structure so that the channel structure with the split structure may be classified as a dummy channel structure. However, because a higher integration degree may be required, characteristics of transistors in the dummy channel structure may be controlled to use a boundary channel structure as a part of a memory cell string.

According to various embodiments, the semiconductor integrated circuit device may additionally compensate electrical characteristics of the boundary channel structure CHPB partially split by the split structure to provide a technology for improving the integration degree.

The split structure 170 may include a split hole H2 and a burying insulation layer 171. The split hole H2 may be formed in the stack structure ST. The burying insulation layer 171 may be formed in the split hole H2. A bottom surface of the split hole H2 may be positioned between a lowermost drain selection line and an uppermost word line. For example, the bottom surface of the split hole H2 may be positioned in the first insulation layer 110 between the third sub-drain selection line DSLc and the nth word line WLn.

The burying insulation layer 171 may include a material substantially the same as the material of the core insulation layer 145. Alternatively, the burying insulation layer 171 may include a material having good gap-filling characteristic.

Referring to FIG. 5, cut surfaces E1 of the sub-drain selection lines DSLa, DSLb and DSLc exposed through a sidewall 170S of the split structure 170 may pull-back cut surfaces E2 of the first insulation layer 110 exposed through the sidewall 170S of the split structure 170. That is, the cut surfaces E1 of the sub-drain selection lines DSLa, DSLb and DSLc may be positioned from the center 170C of the split structure 170 farther the cut surfaces E2 of the first insulation layer 110. In an embodiment, the cut surfaces El may be referred to as first cut surfaces and the cut surfaces E2 may be referred to as second cut surfaces.

Because the cut surfaces El of the sub-drain selection lines DSLa, DSLb and DSLc may be pulled-back than the cut surface El of the first insulation layer 110, a gap g may be generated between the cut surface El of the sub-drain selection lines DSLa, DSLb and DSLc and the cut surface E2 of the first insulation layer 110. The gap g may be filled with the burying insulation layer 171.

Therefore, in an embodiment, by changing the structure of the sidewall in the split structure 170, a parasitic electric field path caused by the split structure may be reduced so that damages caused by a leakage current may also be decreased.

Particularly, as shown in FIG. 6, the split hole H2 for forming the split structure 170 may be formed by sequentially etching an upper region of the stack structure ST, i.e., the second insulating interlayer 165, the first insulating interlayer 120, the sub-drain selection lines DSLa, DSLb and DSLc including the conductive layer and the first insulation layer 110 between the conductive layers.

Because the second insulating interlayer 165, the first insulating interlayer 120, the sub-drain selection lines DSLa, DSLb and DSLc and the first insulation layer 110 may have different properties, although an etching process may be performed using etching agents having good etching characteristics with respect to the materials to form the split hole H2, as shown in FIG. 6, the sidewall of the split hole H2 may have an uneven shape. Particularly, because the conductive layers in the sub-drain selection lines DSLa, DSLb and DSLc may include the metal layer such as tungsten, an etching rate of the conductive layers may be slower than an etching rate of the insulation layers 110, 120 and 165. Particularly, a thickness of the first insulation layer 110 adjacent to the sub-drain selection lines DSLa, DSLb and DSLc may be thinner than a thickness of the sub-drain selection lines DSLa, DSLb and DSLc. After performing the etching for forming the split hole H2, the cut surfaces El of the sub-drain selection lines DSLa, DSLb and DSLc may inwardly protrude towards the split hole H2 more than the cut surfaces E2 of the insulation layers 110, 120 and 165.

In an embodiment, the uneven protrusion of the cut surfaces El of the sub-drain selection lines DSLa, DSLb and DSLc from the sidewall of the split hole H2 may cause a parasitical electric filed together with etch residuals in the first insulation layer 110. In an embodiment, the uneven protrusion may generate damages such as fumes in the split structure 170.

According to various embodiments, as shown in FIG. 7, the sub-drain selection lines DSLa, DSLb and DSLc unevenly protruded from the sidewall 170S of the split hole H2 may be partially recessed. Thus, the cut surface El of the sub-drain selection lines DSLa, DSLb and DSLc may be positioned outside a center line 170c of the split hole H2, or a center of the split structure rather than the cut surface E2 of the first insulation layer 110. That is, a distance dl between the center line 170c of the split hole H2 and the cut surface El of the sub-drain selection lines DSLa, DSLb and DSLc may be longer than a distance d2 between the center line 170c of the split hole H2 and the cut surface E2 of the first insulation layer 110.

Therefore, in an embodiment, the parasitic electric field, which may be generated by directly exposing the cut surface El of the sub-drain selection lines DSLa, DSLb and DSLc without an interposing of the first insulation layer 110, may be prevented or mitigated to suppress the split structure 170 from being damaged. Further, in an embodiment, an electrical short between the cut surface El of the protruded sub-drain selection lines DSLa, DSLb and DSLc may also be prevented or mitigated.

Further, in an embodiment, the center line 170C of the split hole H2 may be substantially the same as the center line 170C of the split structure 170.

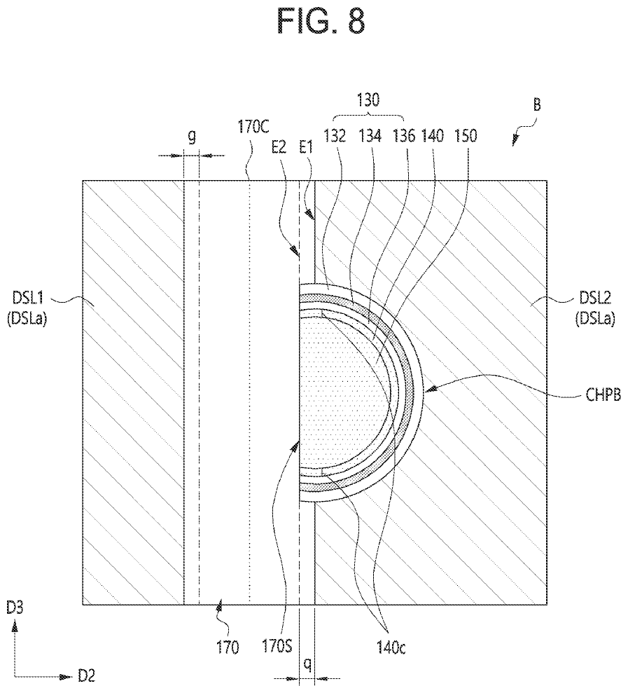

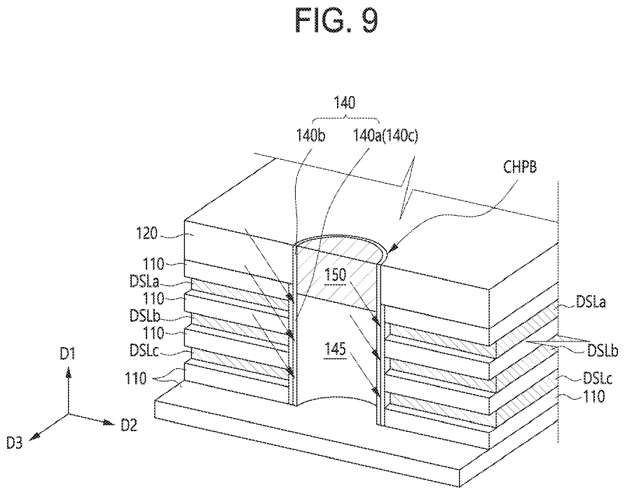

FIG. 8 is a plan view illustrating a boundary channel structure with a split structure in accordance with various embodiments and FIG. 9 is a perspective view illustrating a boundary channel structure in accordance with various embodiments.

As mentioned above, the electrical problems, which may be generated at the sidewall of the split structure 170, may be solved, in an embodiment, by recessing the cut surface of the sub-drain selection lines DSLa, DSLb and DSLc.

However, in an embodiment, an effective area of a gate in the drain selection transistors DST1˜DST3 of the boundary channel structure CHPB may be reduced by changing an area or a size of the sub-drain selection lines DSLa, DSLb and DSLc.

Generally, when the effective area of the gate, i.e., an area of the gate may be decreased, a threshold voltage of a transistor may be changed so that the transistor may malfunction. That is, in an embodiment, operational conditions of the boundary channel structure CHPB may be changed by the recess process of the sub-drain selection lines DSLa, DSLb and DSLc for reducing the electrical problem in the split structure 170.

Thus, as shown in FIGS. 8 and 9, in an embodiment, in order to compensate the operation conditions of the boundary channel structure CHPB, the concentration of the channel layer 140 exposed through the split hole H2 may be controlled.

In various embodiments, first conductive type impurities having a second concentration may be additionally implanted into the channel layer 140 exposed through the split hole H2. The second concentration may be substantially equal to or different from the concentration of the first channel region 140a in the normal channel structure CHP. For example, the second concentration may be set in accordance with recessed amounts of the sub-drain selection lines DSLa, DSLb and DSLc, or a volume of the gap g and the operational characteristics of the drain selection transistors in the boundary channel structure CHPB. However, the first concentration and the second concentration may be a low concentration. The first conductive type impurities may include boron ions.

Further, the additional implantation of the first conductive type impurities may be performed on the entire channel layer 140. However, in an embodiment, only the concentration of the first channel region 140a corresponding to the channel layer 140c of the drain selection transistors DST1˜DST3 may be changed. For example, in an embodiment, the impurity concentration of the channel layer 140c in the boundary channel structure CHPB may be increased to improve the operational characteristics of the drain selection transistors DST1˜DST3.

As mentioned above, in an embodiment, because the second channel region 140b around the capping pattern 150 may include the second conductive type impurities having the high concentration opposite to the first channel region 140a, although the first conductive type impurities having the second concentration may be additionally implanted into the second channel region 140b, the impurity concentration of the second channel region 140b might not be changed.

Therefore, in an embodiment, the concentration of the channel layer 140 facing the split structure 170 in the boundary channel structure CHPB may be controlled to compensate the operational characteristics of the drain selection transistors DST1˜DST3 of the boundary channel structure CHPB.

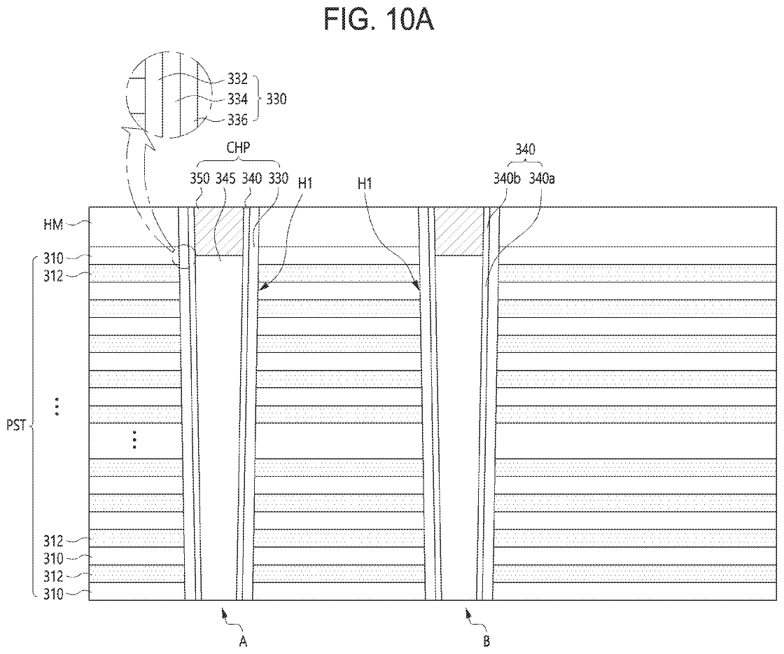

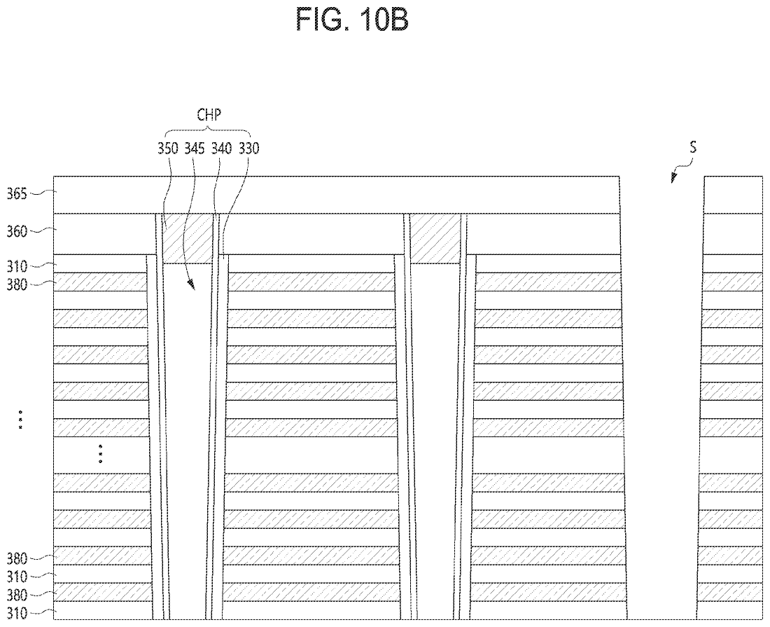

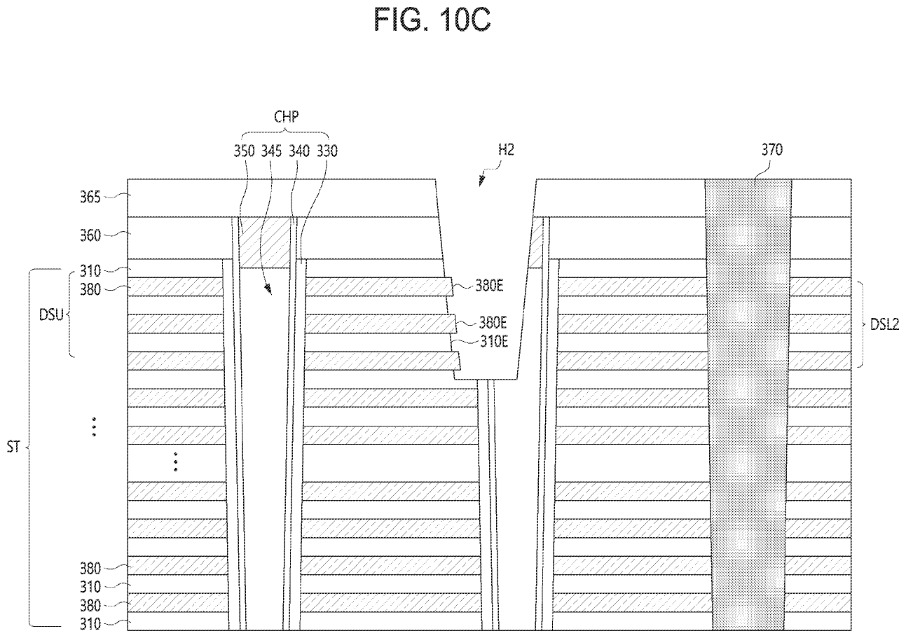

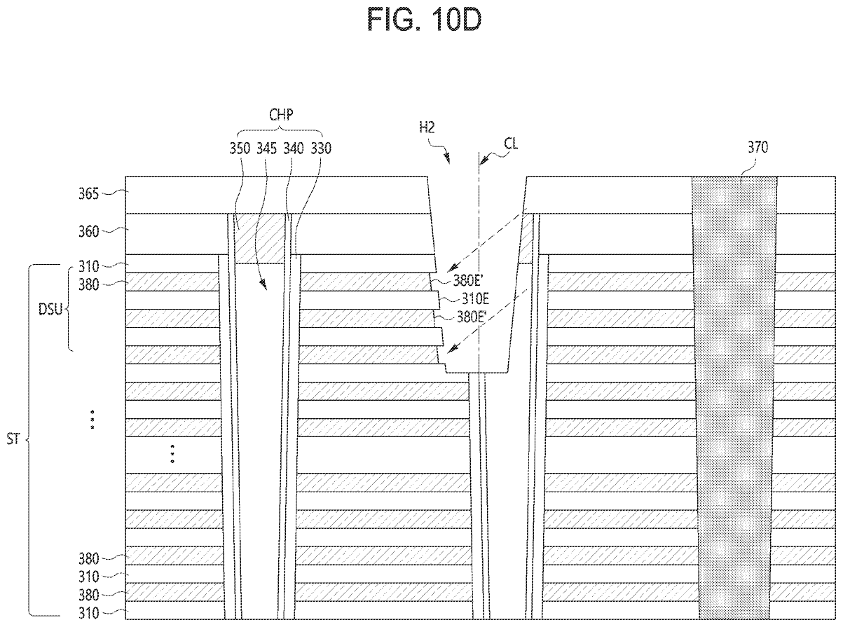

FIGS. 10A to 10D are cross-sectional views illustrating a method of manufacturing a semiconductor integrated circuit device in accordance with various embodiments.

Referring to FIG. 10A, a preliminary stack structure PST may be formed on a lower structure. The lower structure may include a substrate, a semiconductor layer for forming a peripheral circuit layer, a common source layer, etc.

The preliminary stack structure PST may be formed by alternately stacking a first insulation layer 310 and a sacrificial layer 312. The sacrificial layer 312 may have an etching selectivity with respect to the first insulation layer 310. For example, the first insulation layer 310 may include a silicon oxide layer. The sacrificial layer 312 may include a second insulation layer, for example, a silicon nitride layer having an etching selectivity different from an etching selectivity of the first insulation layer 310, not limited thereto. The first insulation layer 310 may correspond to an uppermost layer in the preliminary stack structure PST.

After forming a hard mask pattern HM on the preliminary stack structure PST, an etching process may be performed to form a channel hole H1 through the hard mask pattern HM and the preliminary stack structure PST.

A blocking insulation layer 332, a data storage layer 334 and a tunnel insulation layer 335 may be sequentially formed on a sidewall of the channel hole H1 to form a memory layer 330. A channel layer 340 may be formed on a surface of the memory layer 330, particularly, a surface of the tunnel insulation layer 336. The channel layer 340 may include first conductive type impurities having a first concentration. For example, the first conductive type impurities may include p type impurities such as boron ions. The first concentration may be any one of impurity concentrations classified into a light concentration group in semiconductor fabrication processes.

A core insulation layer 345 may be formed in the channel hole H1 surrounded by the memory layer 330 and the channel layer 340. In various embodiments, the channel hole H1 may be fully or partially filled with the core insulation layer 345. An upper surface of the core insulation layer 345 may be etched to form a groove at the upper surface of the core insulation layer 345. A capping pattern 350 may be formed in the groove to form a channel structure CHP. The capping pattern 350 may include a semiconductor pattern having second conductive type impurities. The capping pattern 350 may be to be contacted with a bit line. The capping pattern 350 may include impurities having a high concentration. In various embodiments, the capping pattern 350 may be formed by forming a polysilicon layer in the groove and by implanting the second conductive type impurities, i.e., the n type impurities having the high concentration into the polysilicon layer. During implanting the n type impurities having the high concentration, the n type impurities may diffuse into the channel layer 340 surrounding the capping pattern 350.

Thus, the channel layer 340 may be classified into a first channel region 340a and a second channel region 340b. The first channel region 340 may be used for channels of a transistor in a memory cell string. The second channel region 340b may make contact with the capping pattern 350. The first channel region 340a may have the first conductive type having the first concentration. The second channel region 340b may have the second conductive type having the second concentration.

Referring to FIG. 10B, the hard mask pattern HM may then be removed. While removing the hard mask pattern HM, the memory layer 330 adjacent to the hard mask pattern HM may also be removed. By removing the hard mask pattern HM, the capping pattern 350 and the second channel region 340b surrounding the capping pattern 350 may be exposed.

A first insulating interlayer 360 may be formed on the first insulation layer 310. The capping pattern 350 may be surrounded by the first insulating interlayer 360. A second insulating interlayer 365 may be formed on the first insulating interlayer 360.

The first insulating interlayer 360, the first insulating layer 310 and the second insulation layer 320 in a predetermined region of the preliminary stack structure PST may be etched to form a slit S. The second insulation layer 320 may be selectively removed through a sidewall of the slit S. A conductive layer 380 may be replaced in a space between the first insulation layers 310 formed by removing the second insulation layer 320. In various embodiments, the conductive layer 380 may include a tungsten layer having conductivity and gap-filling characteristics.

Therefore, the conductive layers 380 may be operated as at least one sub-source selection lines SSLa, SSLb and SSLc, word lines WL0˜WLn and at least one sub-drain selection lines DSLa, DSLb and DSLc.

In various embodiments, after selectively removing the sacrificial layer 312, the conductive layer 380 may be replaced. Alternatively, a conductive layer in place of the sacrificial layer 312 may be directly formed.

The preliminary stack structure PST may have a size similar to a size of a memory block by forming the slit S. Further, a stack structure ST for forming the memory block may be defined by the replace process of the conductive layer 380.

Referring to FIG. 10C, the slit S may be filled with at least one layer to form a slit structure 370. In various embodiments, the slit structure 370 may include at least one insulation material for preventing or mitigating an electrical problem between the adjacent stack structure ST and the slit structure 370.

A mask pattern for splitting a drain selection line may be formed on the stack structure ST. The second insulating interlayer 365, the first insulating interlayer 360, the first insulation layer 310 and the conductive layers 380 to be used for the drain selection line may be etched using the mask pattern as an etch mask to form a split hole H2. The conductive layers 380 may be split into a plurality of sub-drain selection lines in a first drain selection line group DLS1 and a plurality of sub-drain selection lines in a second drain selection line group DSL2 by the slit hole H2.

The etching process for forming the split hole H2 may be performed on the second insulating interlayer 365, the first insulating interlayer 360 and the first insulation layers 310 including silicon oxide and the conductive layers 380 including tungsten. Thus, the etching process may be performed under a plasma atmosphere using an etching gas including fluorine.

As mentioned above with reference to FIG. 6, in the etching process for forming the split hole H2, a cut surface 380E of the conductive layers 380 corresponding to the sub-drain selection line may be inwardly protruded into the split hole H2 than a cut surface 310E of the first insulation layer 310 due to a difference between etching selectivities of the silicon oxide and the tungsten. Residuals generated by the plasma etching process may be charged. The charged residuals may remain the sidewall of the split hole H2. In an embodiment, the remaining residuals may cause a parasitic electric field and a leakage current.

Referring to FIG. 10D, a cut surface 380E′ of the conductive layer 380 exposed through the sidewall of the split hole H2 may be recessed or pulled-back. The recess process may be performed using an etching agent having good etching characteristics with respect to the conductive layer 380 than the first insulation layer 310.

The cut surface 380E′ of the conductive layer 380 may be spaced apart from a center line CL of the split hole H2 than the cut surface 310E of the first insulation layer 310 by the recess process. Thus, in an embodiment, the cut surface 380E′ of the conductive layer 380 may be covered by the first insulation layers 310, not exposed, to prevent or mitigate the electrical problem caused by the leakage current.

Further, as mentioned above with reference to FIG. 9, in an embodiment, in order to compensate deformations of operational characteristics of a drain selection transistor in a boundary channel structure CHPB caused by the recess process of the conductive layers 380 in the sub-drain selection line, first conductive type impurities, for example, boron ions may be additionally implanted into the channel layer exposed through the split hole H2. Although not depicted in FIG. 10D, a burying insulation layer may be formed in the split hole H2 to form a slit structure 170 in FIG. 3. A bit line contact plug maybe formed in the second insulating interlayer 365. A bit line may be electrically connected to the bit line contact plug.

According to various embodiments, when the split structure may be formed, the conductive layers for the drain selection line exposed through the sidewall of the split structure, which may be caused by non-uniformity of an etching between the conductive layer and the insulation layer, may be recessed. Thus, in an embodiment, a damage to the sidewall of the split structure may be reduced.

Further, in an embodiment, the boron ions may be implanted into the boundary channel structure cut by the split structure to compensate the characteristics of the selection transistor connected to the boundary channel structure.

In various embodiments, one memory stack may be exemplarily explained. However, various embodiments may be applied to a plurality of the memory stacks.

Further, various embodiments may include the slit structure configured to split the drain selection line. Alternatively, various embodiments may be applied to structures having various kinds of holes formed through the conductive layer and the insulation layer.

The above described embodiments are intended to illustrate and not to limit the present disclosure. Various alternatives and equivalents are possible. The embodiments are not limited by the embodiments described herein. Nor are the embodiments limited to any specific type of semiconductor device.

What is claimed is:

1. A semiconductor integrated circuit device comprising:
a stack structure including a plurality of insulation layers and a plurality of conductive layers alternately stacked;
a split structure configured to split at least one selected conductive layer among the conductive layers from the insulation layers adjacent to the selected conductive layer;
a plurality of channel structures spaced apart from the split structure and formed in the stack structure; and
at least one boundary channel structure configured to partially make contact with the split structure and formed in the stack structure, wherein a cut surface of the selected conductive layer split by the split structure is positioned from a center of the split structure, farther a cut surface of the insulation layers split by the split structure.

2. The semiconductor integrated circuit device of claim 1,
wherein each of the channel structures and the boundary channel structure comprises a first conductive type channel layer extended in a first direction.

3. The semiconductor integrated circuit device of claim 2,
wherein the channel layer of the boundary channel structure has a concentration different from a concentration of the channel layer of the channel structures.

4. The semiconductor integrated circuit device of claim 1,
wherein the conductive layers comprise at least one word line and at least one drain selection line on the word line, and the selected conductive layer comprises the at least one drain selection line.

5. The semiconductor integrated circuit device of claim 1,
wherein each of the channel structures comprises:
a cylindrical channel layer formed through the insulation layers and the conductive layers;
a memory layer arranged on a surface of the channel layer; and
a capping pattern surrounded by the channel layer and electrically connected with the channel layer.

6. The semiconductor integrated circuit device of claim 5,
wherein the boundary channel structure comprises:
a channel layer formed through the insulation layers and the conductive layers;
a memory layer formed on the channel layer; and
a capping pattern formed on the channel layer,
wherein the channel layer, the memory layer and the capping pattern in the boundary channel structure are directly connected to the split structure.

7. The semiconductor integrated circuit device of claim 6,
wherein each of the capping patterns of the channel structures and the boundary channel structure comprises second conductive type impurities opposite to a first conductive type impurities of the channel layer.

8. A semiconductor integrated circuit device comprising:
a stack structure including at least one source selection line, a plurality of word lines and at least one drain selection line stacked in a first direction, an insulation layer interposed between the source selection line, the word lines and the drain selection line;
a plurality of channel structures including a cylindrical channel layer extended in the stack structure along the first direction to face the source selection line, the word lines and the drain selection line; and
a split structure formed in the stack structure, the split structure directly connected with at least one of the channel structures to split the drain selection lines into a plurality of lines,
wherein a cut surface of the drain selection line is directly connected with the split structure, and a cut surface of the insulation layer and a cut surface of the channel structure are positioned adjacent to the drain selection line,
wherein the cut surface of the drain selection line is positioned from a center line of the split structure by a first distance and the cut surface of the channel structure is positioned from a center line of the spit structure by a second distance,
wherein the first distance is greater than the second distance, and
wherein an impurity concentration of the channel layer in the channel structure contacted with the split structure is different from an impurity concentration of the channel layer in the channel structures spaced apart from the split structure.

9. The semiconductor integrated circuit device of claim 8,
wherein the impurity concentration of the channel layer in the channel structure directly connected with the split structure is greater than the impurity concentration of the channel layer in the channel structures spaced apart from the split structure.

10. The semiconductor integrated circuit device of claim 8,
wherein the cut surface of the insulation layer is positioned more adjacent to the center line of the split structure than the cut surface of the drain selection line.

11. The semiconductor integrated circuit device of claim 8,
wherein the drain selection line is extended in a second direction intersected with the first direction, a planar structure of the split structure is extended in a third direction intersected with the second direction to split the drain selection line extended in the second direction, and the split structure has a depth from an upper surface of the stack structure to a bottom surface of the drain selection line.

12. The semiconductor integrated circuit device of claim 8, wherein each of the channel structures comprises:
a memory layer formed on the cylindrical channel layer;
a core insulation layer formed in a lower space of the cylindrical channel layer; and
a capping pattern formed on the core insulation layer in an upper space of the cylindrical channel layer.

13. The semiconductor integrated circuit device of claim 12,
wherein the channel layer comprises a first channel region positioned on the core insulation layer and a second channel region positioned on the capping pattern, and the first channel region has first conductive type impurities.

14. The semiconductor integrated circuit device of claim 13,
wherein the capping pattern and the second channel region comprise a semiconductor layer with second conductive type impurities opposite to the first conductive type.
